(19) United States
(12) Patent Application Publication
(10) Pub. No.: US 2016/0356825 A1
(43) Pub. Date: Dec. 8, 2016

(54) CURRENT DETECTING CIRCUIT

(71) Applicant: SAMSUNG SDI CO., LTD., Yongin-si (KR)

(72) Inventors: JeongGuk Bae, Yongin-si (KR); Sundaraaman K.V., Yongin-si (KR)

(21) Appl. No.: 15/157,168

(22) Filed: May 17, 2016

(30) Foreign Application Priority Data
Jun. 8, 2015 (KR) 10-2015-0080860

(51) Int. Cl. G01R 19/00; G01R 17/02

(52) U.S. Cl. CPC G01R 19/0092; G01R 17/02

(57) ABSTRACT

A current detecting circuit includes: a shunt resistor; an amplifier; a first signal line connecting a first terminal of the shunt resistor to a first input terminal of the amplifier; a second signal line connecting a second terminal of the shunt resistor to a second input terminal of the amplifier; and a third signal line connecting the second terminal of the shunt resistor to a first power supply terminal of the amplifier.

### CROSS-REFERENCE TO RELATED APPLICATION

This application claims priority to and the benefit of Korean Patent Application No. 10-2015-0080860, filed in the Korean Intellectual Property Office on Jun. 8, 2015, the entire content of which is incorporated herein by reference.

### BACKGROUND

1. Field

Aspects of embodiments of the present invention relate to a current detecting circuit.

2. Description of the Related Art

A shunt resistor may be arranged on a predetermined current path to measure a current according to a voltage by amplifying both voltages.

For example, in order to measure a minute current difference, a resistance value of the shunt resistor may be precisely manufactured. The resistance value of the shunt resistor is generally very low, and as a result, easily influenced by a resistance value generated according to a pattern of a connected wire. Therefore, how to design the pattern of the wire is an important consideration for designers.

Further, the current detecting circuit utilizing the shunt resistor may remove noise so as to measure a minute current change. The noise is largely divided into a common mode noise and a differential mode noise.

The common mode noise is noise having the same phase generated for ground terminals in two signal lines. In order to remove the common mode noise, there are various methods, but as one example, there is a method of connecting bypass capacitors C21 and C22 between the ground terminals and each of two signal lines L221 and L22 (see FIG. 4). The noise which is an AC component flows to the path through the bypass capacitors C21 and C22. The differential mode noise may be removed by setting a current path through the bypass capacitors C21 and C22.

However, referring to FIG. 4, an impedance 51 exists between the ground terminal connected with the bypass capacitors C21 and C22 and the ground terminal connected with a first power supply Vee of an amplifier 31. That is, the aforementioned two ground terminals are ground terminals that are physically different from each other to have a potential difference. Accordingly, a common mode current according to a potential difference flows, and it is difficult to detect an accurate current due to a noise component carried on the common mode current.

Further, because the position of the ground terminal connected with the bypass capacitors C21 and C22 is different from the position of the ground terminal connected to the first power supply Vee of the amplifier 31, different noise may be transferred.

Accordingly, aspects of the present invention include a current detecting circuit having a new structure for solving the aforementioned problems.

The above information disclosed in this Background section is only for enhancement of understanding of the background of the invention and therefore it may contain information that does not constitute prior art.

### SUMMARY

Aspects of embodiments of the present invention relate to a current detecting circuit, and to a current detecting circuit including a shunt resistor.

Aspects of embodiments of the present invention include a current detecting circuit having advantages of improving current accuracy.

According to aspects of some embodiments of the present invention, a current detecting circuit includes: a shunt resistor; an amplifier; a first signal line connecting a first terminal of the shunt resistor to a first input terminal of the amplifier; a second signal line connecting a second terminal of the shunt resistor to a second input terminal of the amplifier; and a third signal line connecting the second terminal of the shunt resistor to a first power supply terminal of the amplifier.

The current detecting circuit may further include: a first capacitor connecting the first signal line to the third signal line; and a second capacitor connecting the second signal line to the third signal line.

A pattern of the third signal line may be between a pattern of the first signal line and a pattern of the second signal line.

An impedance of the first signal line may be matched with an impedance of the second signal line.

An impedance of the third signal line may be matched with the impedance of the first signal line and the impedance of the second signal line.

The impedances of the first, second, and third signal lines may be determined according to a shape of each signal line pattern.

A capacitance of the first capacitor and a capacitance of the second capacitor may be determined according to a frequency value of an environmental noise.

The capacitance of the first capacitor and the capacitance of the second capacitor may have a same value.

A second power supply terminal of the amplifier may be connected to a fixed voltage source; and a voltage applied to the second power supply terminal may be larger than a voltage applied to the first power supply terminal.

The shunt resistor may be positioned on a high current path of a battery protective circuit.

A polarity of both voltages of the shunt resistor when the battery protective circuit is in a charge mode may be different from a polarity of the both voltages of the shunt resistor when the battery protective circuit is in a discharge mode.

An output of the amplifier may be input to an analog to digital converter (ADC), and a current flowing in the shunt resistor may be measured according to an output of the ADC.

The first power supply terminal may be a ground terminal.

According to aspects of some embodiments of the present invention, it may be possible to provide a current detecting circuit with improved current accuracy.

### BRIEF DESCRIPTION OF THE DRAWINGS

FIG. 1 is a diagram illustrating a battery pack according to an example embodiment of the present invention.

FIG. 2 is a diagram illustrating a current detecting circuit according to the example embodiment of the present invention.

FIG. 3 is a diagram illustrating a part of the current detecting circuit implemented on a printed circuit board (PCB) according to the example embodiment of the present invention.

FIG. 4 is a diagram illustrating a current detecting circuit in the related art.

### DETAILED DESCRIPTION

Aspects of embodiments of the present invention will be described more fully hereinafter with reference to the accompanying drawings, in which example embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

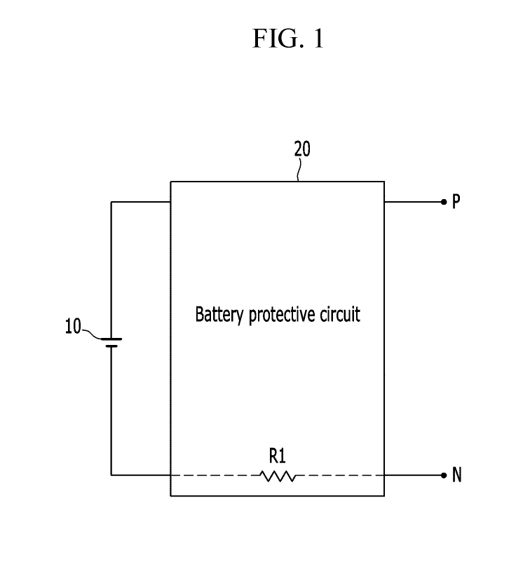

FIG. 1 is a diagram illustrating a battery pack according to an example embodiment of the present invention.

Referring to FIG. 1, a battery pack according to an example embodiment of the present invention includes a battery 10 and a battery protective circuit 20.

The battery protective circuit 20 is interposed between an anode and an external terminal P of the battery 10 and between a cathode and an external terminal N of the battery 10 to be positioned on a high current path.

The battery protective circuit 20 includes a charging field effect transistor and a discharging field effect transistor that are connected to each other in series to control charging and discharging according to a control of a controller. The charging field effect transistor and the discharging field effect transistor may not operate well and, as a result, when overdischarging or overcharging occurs, the controller disconnects a fuse that is a secondary protective element to block the high current path. A protecting operation of the battery protective circuit 20 is an example embodiment, and the present invention is not limited thereto.

The battery protective circuit 20 of the present invention includes a shunt resistor R1 in order to perform a protection function of the battery 10. For example, in a charging mode, when the current flows to a discharging direction or a current over a predicted current flows, the current may be detected through the shunt resistor R1 and the battery protective circuit 20 may operate.

The shunt resistor R1 may be arranged at a position to measure a current change. The shunt resistor R1 may be positioned on the high current path of the battery protective circuit 20.

When the shunt resistor R1 is positioned on the high current path of the battery protective circuit 20, polarities of both voltages may be changed according to a mode of the battery protective circuit 20. That is, a polarity of the both voltages of the shunt resistor R1 when the battery protective circuit 20 is in the charging mode and a polarity of both voltages of the shunt resistor R1 when the battery protective circuit 20 is in the discharging mode are different from each other. The charging current in the charging mode and the discharging current in the discharging mode have different directions.

The charging current in the charging mode flows in order of the external terminal P, the battery protective circuit 20, the anode of the battery 10, the cathode of the battery 10, the battery protective circuit 20, and the external terminal N. The discharging current in the discharging mode flows in order of the external terminal N, the battery protective circuit 20, the cathode of the battery 10, the anode of the battery 10, the battery protective circuit 20, and the external terminal P.

An external device such as a load or a generator is connected to the external terminal P and the external terminal N.

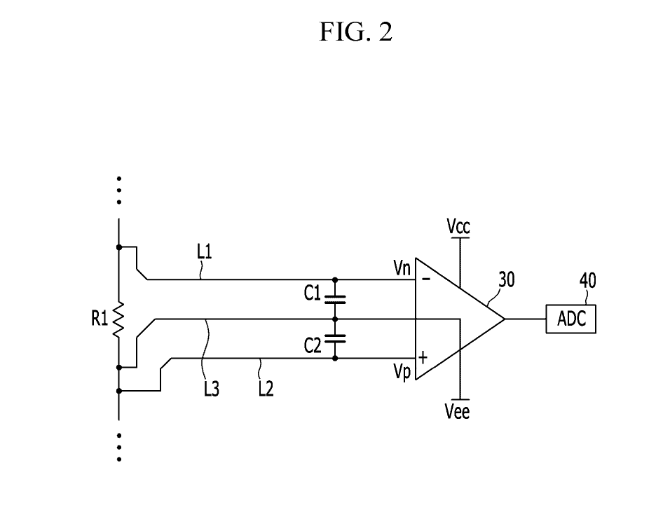

In FIG. 1, the shunt resistor R1 is positioned on the high current path between the cathode of the battery 10 and the external terminal N. As another example embodiment, the shunt resistor R1 may be positioned on the high current path between the anode of the battery 10 and the external terminal P. The position of the shunt resistor R1 may be determined by considering a voltage level that is applied to the first and second power supply terminals Vcc and Vee of the amplifier 30 of FIG. 2.

FIG. 2 is a diagram illustrating a current detecting circuit according to the example embodiment of the present invention.

Referring to FIG. 2, the current detecting circuit according to the example embodiment of the present invention includes the shunt resistor R1, first to third signal lines L1, L2, and L3, first and second capacitors C1 and C2, the amplifier 30, and an analog to digital converter (ADC) 40.

The first signal line L1 connects one terminal of the shunt resistor R1 and a first input terminal Vn of the amplifier 30 to each other. The second signal line L2 connects the other terminal of the shunt resistor R1 and a second input terminal Vp of the amplifier 30 to each other. The third signal line L3 connects the other terminal of the shunt resistor R1 and the first power supply terminal Vee of the amplifier 30 to each other. In this case, the first power supply terminal Vee may be a ground terminal of the amplifier 30.

Hereinafter, in the present invention, the “connecting” of two elements to each other means “electrically connecting” the two elements to each other as long as a function to be achieved is performed. The “electrically connecting” of the two elements to each other means that a positive element or an active element may be interposed therebetween. That is, because another element is interposed on a predetermined path of the current detecting circuit illustrated in FIG. 2, a person having ordinary skill in the art should recognize that certain modifications to the described embodiments may be made to have additional features or aspects, without departing from the spirit and scope of the present invention.

The first capacitor C1 connects the first signal line L1 and the third signal line L3 to each other. The second capacitor C2 connects the second signal line L2 and the third signal line L3 to each other.

The first and second capacitors C1 and C2 as a bypass capacitor serve to reduce the common mode noise and the differential mode noise as described above.

As one example embodiment, a capacitance value of the first capacitor C1 and a capacitance value of the second capacitor C2 may be the same as or similar to each other. This is to match impedance of the pattern configured by each signal line with each other, and the capacitance values of the capacitors may be different from each other according to a detailed pattern.

The capacitance values of the first capacitor C1 and the second capacitor C2 may be determined according to a frequency value of the noise that is frequently applied in an environment where the current detecting circuit of the present invention is used. The first capacitor C1 and the second capacitor C2 serve to reduce the noise by bypassing an AC component of the noise. In this case, because the frequency value of the applied noise varies according to the environment where the current detecting circuit is used, the capacitance values of the first capacitor C1 and the second capacitor C2 are determined to efficiently remove the noise.

The amplifier 30 may be an operational amplifier (OP AMP). The amplifier 30 may be configured by a single power or double power OP AMP. Input and output terminals of the amplifier 30 may vary according to a product. It is described that the amplifier 30 in the present invention includes two input terminals Vn and Vp, two power supply terminals Vcc and Vee, and one out terminal.

The amplifier 30 amplifies and outputs a difference between the first voltage input to the first input terminal Vn and the second voltage input to the second input terminal Vp with a predetermined ratio. In the example embodiment, the first voltage is a voltage of one terminal of the shunt resistor R1, and the second voltage is a voltage of the other terminal of the shunt resistor R1. The first input terminal Vn and the second input terminal Vp may be used to be replaced with each other.

The third signal line L3 connects the other terminal of the shunt resistor R1 and the first power supply terminal Vee of the amplifier 30 to each other through the same voltage node. Accordingly, one terminal of each of the first and second capacitors C1 and C2 and the first power supply terminal Vee are positioned on the same voltage node. As described above, the first power supply terminal Vee may be a ground terminal of the amplifier 30.

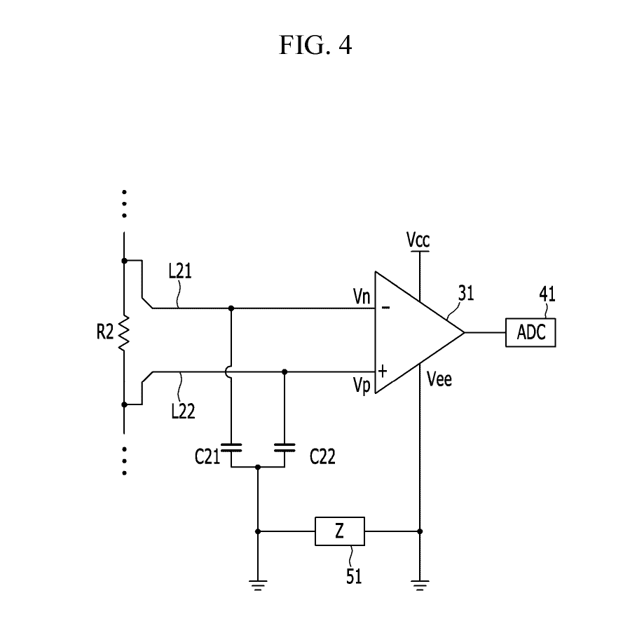

As described above, referring to FIG. 4, in a current protective circuit in the related art, the ground terminal of the bypass capacitors C21 and C22 and the ground terminal of the first power supply terminal Vee are different from each other to have a potential difference. Accordingly, there is a problem in that mismatch of the potentials is amplified in the amplifier, and as a result, an undesired signal may be amplified.

However, in the present invention, one terminal of each of the first and second capacitors C1 and C2 and the first power supply terminal Vee are positioned on physically the same voltage node, and as a result, the impedance 51 like FIG. 4 is not interposed therebetween. Accordingly, a cause of the common mode noise is removed to improve quality of the output signal.

The second power supply terminal Vcc of the amplifier 30 may be connected to a fixed voltage source. In this case, the voltage applied to the second power supply terminal Vcc may be larger than the voltage applied to the first power supply terminal Vee.

As another example embodiment, the second power supply terminal Vcc of the amplifier 30 may be connected to a node having a voltage level higher than that of the first power supply terminal Vee. A potential difference of the first power supply terminal Vee and the second power supply terminal Vcc may be determined by considering an output range of the amplifier 30.

An output of the amplifier 30 is input to the ADC 40, and the current detecting circuit of the present invention may measure the current flowing in the shunt resistor R1 according to an output of the ADC 40. The ADC 40 is a selective configuration, and the current detecting circuit further includes an analog circuit replacing the ADC 40 to measure the current.

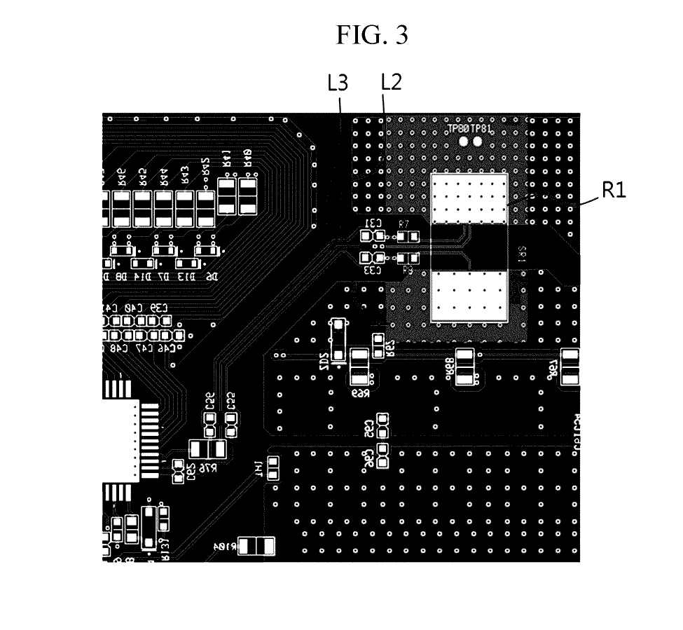

FIG. 3 is a diagram illustrating a part of the current detecting circuit implemented on a printed circuit board (PCB) according to the example embodiment of the present invention.

Referring to FIG. 3, the first to third signal lines Li, L2, and L3 may be patterned on the PCB.

The impedance of the first signal line L1 and the impedance of the second signal line L2 may be matched with each other. When the first signal line L1 and the second signal line L2 are configured by (or formed of) the same material (for example, copper), the patterns of the first signal line L1 and the second signal line L2 may be the same as or similar to each other. That is, because a length, a width, and a shape of the pattern of the first signal line L1 and a length, a width, and a shape of the pattern of the second signal line L2 are the same as or similar to each other, impedance matching may be implemented.

The third signal line L3 is patterned between the first and second signal lines L1 and L2. Accordingly, because a distance between the third signal line L3 and the first signal line L1 and a distance between the third signal line L3 and the second signal line L2 are the same as or similar to each other, impedance matching of the first and second signal lines L1 and L2 may be more easily obtained in some instances.

In this case, the pattern of the third signal line L3 is similarly configured to the pattern of the first or second signal line L1 or L2, and as a result, the impedance of the third signal line L3 may be matched with the impedance of the first or second signal line L1 or L2.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims, and their equivalents.

### DESCRIPTION OF SOME OF THE SYMBOLS

10: Battery
20: Battery protective circuit
R1: Shunt resistor
L1: First signal line
L2: Second signal line
L3: Third signal line
C1: First capacitor
C2: Second capacitor
30: Amplifier
40: ADC

What is claimed is:

1. A current detecting circuit, comprising:
a shunt resistor;
an amplifier;
a first signal line connecting a first terminal of the shunt resistor to a first input terminal of the amplifier;
a second signal line connecting a second terminal of the shunt resistor to a second input terminal of the amplifier; and
a third signal line connecting the second terminal of the shunt resistor to a first power supply terminal of the amplifier.

2. The current detecting circuit of claim 1, further comprising:
a first capacitor connecting the first signal line to the third signal line; and
a second capacitor connecting the second signal line to the third signal line.

3. The current detecting circuit of claim 2, wherein:
a pattern of the third signal line is between a pattern of the first signal line and a pattern of the second signal line.

4. The current detecting circuit of claim 3, wherein:
an impedance of the first signal line is matched with an impedance of the second signal line.

5. The current detecting circuit of claim 4, wherein:
an impedance of the third signal line is matched with the impedance of the first signal line and the impedance of the second signal line.

6. The current detecting circuit of claim 5, wherein:
the impedances of the first, second, and third signal lines is determined according to a shape of each signal line pattern.

7. The current detecting circuit of claim 2, wherein:
a capacitance of the first capacitor and a capacitance of the second capacitor are determined according to a frequency value of an environmental noise.

8. The current detecting circuit of claim 7, wherein:
the capacitance of the first capacitor and the capacitance of the second capacitor have a same value.

9. The current detecting circuit of claim 3, wherein:
a second power supply terminal of the amplifier is connected to a fixed voltage source; and
a voltage applied to the second power supply terminal is larger than a voltage applied to the first power supply terminal.

10. The current detecting circuit of claim 3, wherein:
the shunt resistor is positioned on a high current path of a battery protective circuit.

11. The current detecting circuit of claim 10, wherein:
a polarity of both voltages of the shunt resistor when the battery protective circuit is in a charge mode is different from a polarity of the both voltages of the shunt resistor when the battery protective circuit is in a discharge mode.

12. The current detecting circuit of claim 3, wherein:
an output of the amplifier is input to an analog to digital converter (ADC), and
a current flowing in the shunt resistor is measured according to an output of the ADC.

13. The current detecting circuit of claim 1, wherein:
the first power supply terminal is a ground terminal.
